(19) United States
(12) Patent Application Publication
(10) Pub. No.: US 2014/0284799 A1
(43) Pub. Date: Sep. 25, 2014

(54) SEMICONDUCTOR DEVICE AND METHOD OF MANUFACTURING THE SAME

(71) Applicant: Kabushiki Kaisha Toshiba, Minato-ku (JP)

(72) Inventors: Masayuki KATAGIRI, Kanagawa (JP); Tadashi SAKAI, Kanagawa (JP); Hisao MIYAZAKI, Kanagawa (JP); Yuichi YAMAZAKI, Tokyo (JP); Mariko SUZUKI, Kanagawa (JP)

(73) Assignee: Kabushiki Kaisha Toshiba, Minato-ku (JP)

(21) Appl. No.: 14/202,017

(22) Filed: Mar. 10, 2014

(30) Foreign Application Priority Data
Mar. 19, 2013 (JP) 2013-057005

(51) Int. Cl. H01L 23/532; H01L 21/285

(52) U.S. Cl. CPC H01L 23/53276; H01L 21/28506
USPC 257/750; 438/610

(57) ABSTRACT

A semiconductor device has a substrate a lower layer wiring on the substrate, an interlayer dielectric on the lower layer wiring having a contact hole, a catalyst metal layer at the bottom of the contact hole having catalyst metal particles, multi-walled carbon nanotubes on the catalyst metal layer passing through the contact hole, and an upper layer wiring on the multi-walled carbon nanotubes. The multi-walled carbon nanotubes are intercalated with an atomic or molecular species.

### CROSS-REFERENCE TO RELATED APPLICATION

This application is based upon and claims the benefit of priority from Japanese Patent Application No. 2013-057005 Mar. 19, 2013; the entire contents of which are incorporated herein by reference.

### FIELD

Embodiments described herein relate generally to a semiconductor device and a method of manufacturing the same.

### BACKGROUND

Increase in wiring delay in metal wiring with miniaturized multi-layered LSI and 3D memory is a large problem. In order to decrease the wiring delay, it is important to decrease wiring resistance and interwire capacitance. Application of a low-resistance material such as Cu, for example, is put into practical use for decreasing the wiring resistance. Unfortunately, Cu wiring also has problems such as stress-migration- or electromigration-induced degradation of reliability, a size effect-induced increase in electric resistivity, and embedding into fine via holes, and there has been a demand for wiring materials with lower resistance and higher current density tolerance.

Application of a carbon-based material such as a carbon nanotube and a graphene with an excellent physical property such as high current density tolerance, electric conduction property, thermal conductivity, and mechanical strength attracts attention as a next-generation wiring material expected to be low-resistance and highly reliable material. Especially, there have been studied wiring structures having vertical interlayer wiring formed using carbon nanotube.

### BRIEF DESCRIPTION OF THE DRAWINGS

FIG. 1 is a schematic cross-sectional view of a semiconductor device having a wiring according to an embodiment;

FIG. 2 is a schematic cross-sectional view showing a method of manufacturing a wiring according to an embodiment;

FIG. 3 is a schematic cross-sectional view showing a method of manufacturing a wiring according to an embodiment;

FIG. 4 is a schematic cross-sectional view showing a method of manufacturing a wiring according to an embodiment;

FIG. 5 is a schematic cross-sectional view showing a method of manufacturing a wiring according to an embodiment;

FIG. 6 is a schematic cross-sectional view showing a method of manufacturing a wiring according to an embodiment;

FIG. 7 is a schematic cross-sectional view of a semiconductor device having a wiring according to an embodiment;

FIG. 8 is a schematic cross-sectional view showing a method of manufacturing a wiring according to an embodiment;

FIG. 9 is a schematic cross-sectional view showing a method of manufacturing a wiring according to an embodiment;

FIG. 10 is a schematic cross-sectional view showing a method of manufacturing a wiring according to an embodiment;

FIG. 11 is a schematic cross-sectional view of a semiconductor device having a wiring according to an embodiment;

FIG. 12 is a schematic cross-sectional view showing a method of manufacturing a wiring according to an embodiment;

FIG. 13 is a schematic cross-sectional view showing a method of manufacturing a wiring according to an embodiment; and

FIG. 14 is a schematic cross-sectional view of a semiconductor device having a wiring according to an embodiment.

### DETAILED DESCRIPTION

A semiconductor device includes a substrate, a lower layer wiring on the substrate, an interlayer dielectric on the lower layer wiring having a contact hole, a catalyst metal layer at the bottom of the contact hole having catalyst metal particles, multi-walled carbon nanotubes on the catalyst metal layer passing through the contact hole, and an upper layer wiring on the multi-walled carbon nanotubes. The multi-walled carbon nanotubes are intercalated with an atomic or molecular species.

A method of manufacturing a semiconductor device includes forming an interlayer dielectric on a substrate, forming a contact hole through the interlayer dielectric, forming a catalyst metal layer at the contact hole, growing multi-walled carbon nanotubes from the catalyst metal layer, and intercalating the multi-walled carbon nanotubes with an atomic or molecular species.

A semiconductor device includes a substrate, a lower layer wiring on the substrate, an interlayer dielectric on the lower layer wiring having a contact hole, a catalyst metal layer at the bottom of the contact hole having catalyst metal particles, multi-walled carbon nanotubes on the catalyst metal layer passing through the contact hole, an upper layer wiring on the multi-walled carbon nanotubes, and a first filling film in the contact hole. A gap is provided between the first filling film and the upper layer wiring, a second filling film is provided between the first filling film and the upper layer wiring, or top end parts of the multi-walled carbon nanotubes are embedded in the upper layer wiring.

### Embodiment 1

A semiconductor device according to an embodiment includes a semiconductor integrated circuit having a wiring, an interlayer dielectric formed on the wiring and having a contact hole, a catalyst metal layer formed at the bottom of the contact hole and having catalyst metal particles, multi-walled carbon nanotubes formed on the catalyst metal layer and passing through the contact hole, wherein the multi-walled carbon nanotubes are intercalated with an atomic or molecular species to form a carbon nanotube wiring.

The multi-walled carbon nanotubes are intercalated with an atomic or molecular species such as an alkali metal (such as K, Rb, or Li), a halogen (such as F₂ or Br₂), or a chloride (such as FeCl₃, ZnCl₂, CdCl₂, YCl₃, or AlCl₃). When multi-walled carbon nanotubes are intercalated with an atomic or molecular species, their interlayer spacing is widened, and their diameter is increased. In the embodiment, multi-walled carbon nanotubes are formed in the contact hole and then intercalated with an atomic or molecular species so that the diameter of the carbon nanotubes and the space occupancy of the carbon nanotubes in the contact hole are increased. Subsequently, a planarization step is performed, and an upper layer wiring layer is formed. When the space occupancy of the carbon nanotubes is increased, a wiring structure can be formed without forming any filling film.

Hereinafter, a semiconductor device, a wiring, and a method of manufacturing them according to the embodiment will be described with reference to the drawings as needed. The embodiment is illustrative only and should not be construed as limiting. The drawings are illustrative. Meanwhile, the drawings are symmetric and the same reference signs are omitted. Features in the drawings, such as shape, size, and number, do not always correspond to the actual features of a semiconductor device or a structure having a carbon nanotube wiring.

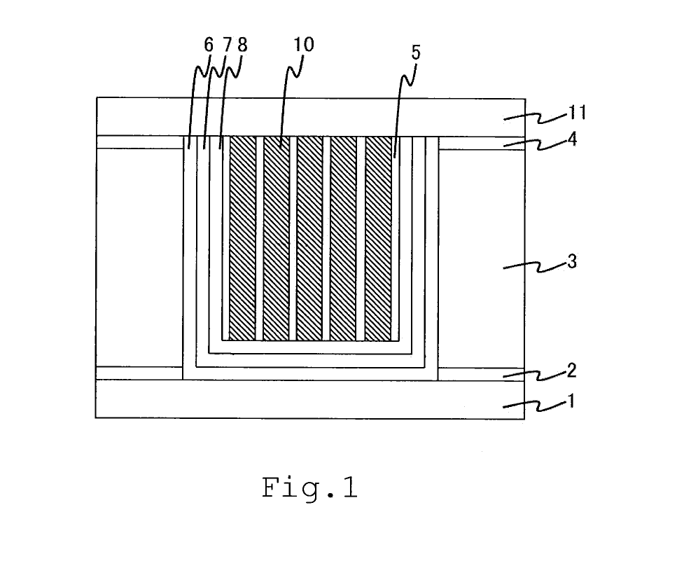

FIG. 1 is a cross-sectional view of an interlayer wiring-containing part of the semiconductor device of the embodiment. FIG. 1 shows a cross-sectional structure of the embodiment, which is a basic feature of the embodiment. An underlying substrate having a semiconductor integrated circuit and other components is omitted from FIG. 1. The semiconductor device of the embodiment includes an underlying substrate having a semiconductor integrated circuit and other components, a lower layer wiring 1 formed on the underlying substrate, an etching stop film 2 on the lower layer wiring 1, an interlayer dielectric 3 on the etching stop film 2, an etching stop film 4 on the interlayer dielectric 3, a contact hole 5 through the etching stop films 2 and 4 and the interlayer dielectric 3, a diffusion preventing film 6 over the bottom and side wall of the contact hole 5, a conductive film 7 on the diffusion preventing film 6, a catalyst metal layer 8 on the conductive film 7, carbon nanotubes 10 grown from a part of the catalyst metal layer 8 at the bottom of the contact hole 5, and an upper layer wiring 11 on the carbon nanotubes 10.

The lower layer wiring 1 and the upper layer wiring 11 on the underlying substrate having a semiconductor integrated circuit and other components are, for example, wirings for the semiconductor integrated circuit.

The etching stop films 2 and 4 function as etching stoppers in the process of forming the interlayer dielectric 3. The etching stop films 2 and 4 are formed using a compound with high etch selectivity over the interlayer dielectric 3, and may be, for example, insulating films of SiCN or the like. The etching stop films 2 and 4 are unnecessary in some cases depending on the manufacturing method and may be used as needed.

The interlayer dielectric 3 is an insulating film used to form the contact hole 5 for the interlayer wiring. For example, the interlayer dielectric 3 is preferably a low-dielectric-constant insulating film of SiOC or the like.

The diffusion preventing film 6 is used to prevent the metal of the conductive film 7 or the catalyst metal layer 8 from diffusing into the interlayer dielectric 3. The diffusion preventing film is, for example, made of a metal or nitride containing at least one element selected from the group consisting of Ti, Ta, Co, Mn, Ru, etc. The thickness of the diffusion preventing film 6 is, for example, from 0.5 nm to 10 nm. The diffusion preventing film 6 may be used as needed.

The conductive film 7 is preferably used under the catalyst metal layer to stabilize or improve the conductivity of the interlayer wiring. A thickness of the conductive film 7 is not less than 0.5 nm and not more than 10 nm, for example. The conductive film 7 is preferably made of a metal capable of serving as a co-catalyst for growth of multi-walled carbon nanotubes. In this case, the conductive film 7 may have a structure of a stack of two or more different conductive materials. For the reason mentioned above, the conductive film 7 is preferably a metal film including a metal or alloy containing at least one element selected from the group consisting of Ti, Ta, Mn, Mo, and V. In some cases, the conductive film 7 contains an inevitable element. The conductive film 7 may be used as needed.

The catalyst metal layer 8 contains an element that enables multi-walled carbon nanotubes to grow. For growth of multi-walled carbon nanotubes, the catalyst metal layer 8 preferably includes a film or particles of a catalyst metal including a metal or alloy containing at least one element selected from the group consisting of Co, Ni, Fe, Ru, and Cu. The carbon nanotube wiring extends from the bottom of the contact hole 5 (the lower layer wiring 1) to the upper layer wiring 11. It is therefore preferable that catalyst metal particles suitable for growth of carbon nanotubes should be provided at at least the bottom of the contact hole 5. The thickness of the catalyst metal layer 8 is, for example, from 1 nm to 10 nm. To form the catalyst metal layer 8 into fine particles, the thickness of the catalyst metal layer 8 is preferably, for example, from 1 nm to 4 nm.

The carbon nanotubes 10 are multi-walled carbon nanotubes. The carbon nanotube structure is preferably a concentric cylindrical structure or a structure having a carbon layer rolled from the center to the outside in the form of a scroll. The carbon nanotubes 10 are multi-walled carbon nanotubes 9 intercalated with an atomic or molecular species. For example, the carbon nanotubes are preferably intercalated with at least one atomic or molecular species selected from the group consisting of alkali metals (such as K, Rb, and Li), halogen molecules (such as F₂ and Br₂), and chloride molecules (such as FeCl₃, ZnCl₂, CdCl₂, YCl₃, and AlCl₃). The intercalation with an atomic or molecular species increases the diameter of multi-walled carbon nanotubes. In the embodiment, for example, the intercalated multi-walled carbon nanotubes have a diameter at least 1.5 times that of carbon nanotubes with no atomic or molecular intercalant although it depends on the amount of intercalation. As the diameter of the carbon nanotubes 10 increases, the occupancy of the carbon nanotubes 10 in the contact hole 5 increases. An atomic or molecular species may be inserted not only between the walls of the multi-walled carbon nanotube 10 but also between the multi-walled carbon nanotubes 10. The insertion of an atomic or molecular species between the multi-walled carbon nanotubes 10 is advantageous in that the conductivity of the carbon nanotubes can be controlled as in the case where an atomic or molecular species is inserted between the walls.

Usually, in the contact hole 5, there is a need to fill the space between the carbon nanotubes 10 with a filling film. In the embodiment, however, there is no need to use a filling film because the carbon nanotubes 10 are entirely thick so that the occupancy of the carbon nanotubes 10 in the contact hole 5 is high enough. Depending on the conditions, the use of a filling film may cause a reaction between the oxide of a filling film and the metal of the upper layer wiring, so that an oxide may be formed to increase the resistance of the interlayer wiring. In this embodiment, however, such an increase in the resistance can be prevented because no filling film is used. The number of carriers in the carbon nanotubes 10 can also be increased, so that the contact resistance with the upper layer wiring 11 can be expected to be reduced.

Whether the multi-walled carbon nanotubes 10 are intercalated with an atomic or molecular species can be checked by cross-sectional analysis using a transmission electron microscope (TEM) or transmission electron microscope energy dispersive X-ray spectrometry (TEM-EDX).

Next, a method of manufacturing the semiconductor device having the carbon nanotube wiring according to the embodiment will be described. A method of manufacturing the semiconductor device having the carbon nanotube wiring according to the embodiment includes, for example, the steps of forming an interlayer dielectric on a substrate, forming a contact hole through the interlayer dielectric, forming a catalyst metal layer at the contact hole, growing multi-walled carbon nanotubes from the catalyst metal layer, and intercalating the multi-walled carbon nanotubes with an atomic or molecular species.

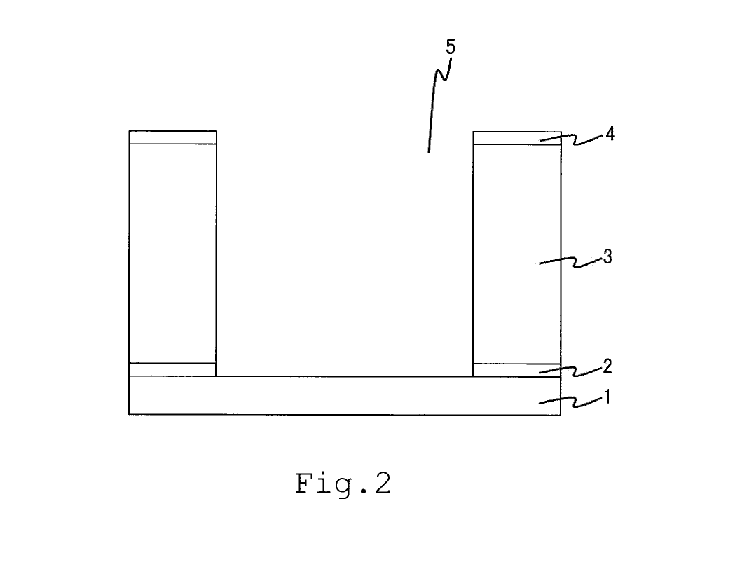

FIG. 2 is a schematic cross-sectional view showing the step of forming a contact hole 5 through a part having a lower layer wiring 1, an etching stop films 2 and 4, and an interlayer dielectric 3, which are formed on an underlying substrate having a semiconductor integrated circuit, according to the embodiment. First, the etching stop film 2 and the interlayer dielectric 3 are formed on the lower layer wiring 1, which is formed on the underlying substrate having a semiconductor integrated circuit and other components. At this time, the second etching stop film 4 may also be formed on the interlayer dielectric 3. Next, dry etching using fluorine-based gas is performed to etch the second etching stop film 4, the interlayer dielectric 3, and the etching stop film 2 so that the contact hole 5 passing through them to the lower layer wiring 1 is formed.

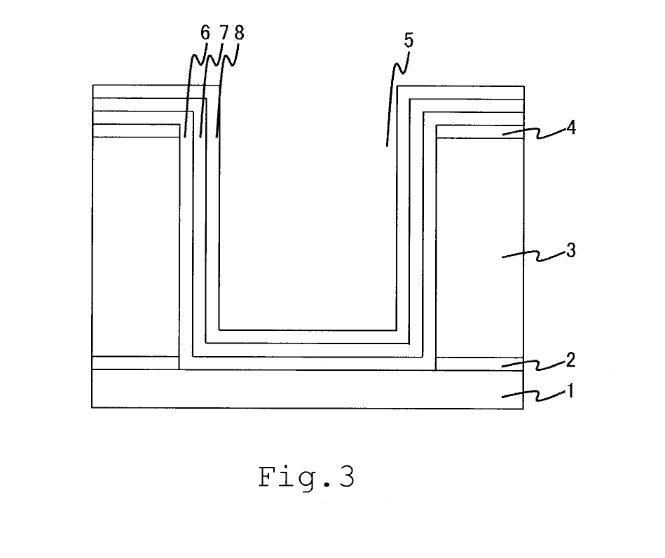

FIG. 3 is a schematic cross-sectional view showing the step of forming a diffusion preventing film 6, a conductive film 7, and a catalyst metal layer 8 on the component shown in the schematic view of FIG. 2. As shown in FIG. 3, a diffusion preventing film 6, a conductive film 7, and a catalyst metal layer 8 are formed over the surface including the surface of the contact hole 5. The diffusion preventing film 6, the conductive film 7, and the catalyst metal layer 8 can be formed using a film deposition method such as physical vapor deposition (PVD) or chemical vapor deposition (CVD). However, when the contact hole has a high aspect ratio (contact hole height/hole diameter), PVD such as sputtering, which provides low step coverage, has difficulty in forming the diffusion preventing film 6, the conductive film 7, and the catalyst metal layer 8 at the via bottom. Therefore, the films are preferably formed using CVD which provides good step coverage. The diffusion preventing film 6 and the conductive film 7 may be omitted from the structure. The diffusion preventing film 6 is preferably used to prevent diffusion of components from the conductive film 7 and the catalyst metal layer 8 into the interlayer dielectric 3.

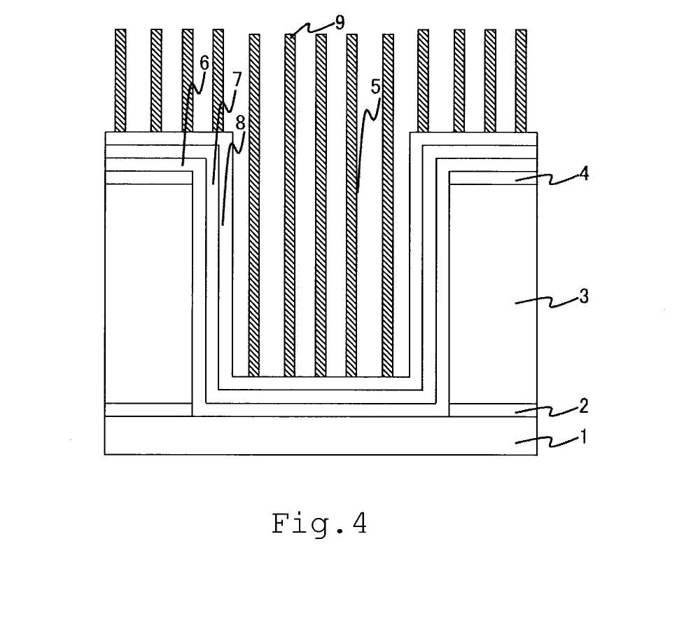

Next, FIG. 4 is a schematic cross-sectional view showing the step of growing multi-walled carbon nanotubes 9 from the catalyst metal layer 8 on the component shown in the schematic view of FIG. 3. The carbon nanotubes 9 can be grown, for example, using a thermal CVD technique or a plasma CVD technique. When a plasma CVD technique is used, the carbon nanotubes 9 can be grown by a process including heating the substrate, for example, to 500° C. in a reactor, introducing hydrocarbon-based gas such as methane gas as raw material gas and hydrogen as carrier gas into the reactor, subjecting methane gas to excitation and discharge, for example, using a microwave to convert the raw material gas into a plasma, and allowing the plasma to react with the catalyst metal layer 8. Before the carbon nanotubes 9 are grown, a plasma surface treatment may be performed to form the catalyst metal layer 8 into fine particles. Alternatively, the catalyst metal layer 8 may also be formed into fine particles by the process of growing the carbon nanotubes 9. The material gas of the plasma is preferably hydrogen or rare gas such as argon, for example; however, this may be mixed gas including any one of or both of them. At that time, the substrate may be heated. The grown carbon nanotubes 9 have a multi-walled structure and a concentric cylindrical structure or a structure having a carbon layer rolled from the center to the outside in the form of a scroll. After the growth of the carbon nanotubes 9, a treatment for opening the end of the multi-walled carbon nanotubes, such as an oxygen plasma treatment or an annealing treatment in an oxygen atmosphere, is preferably performed.

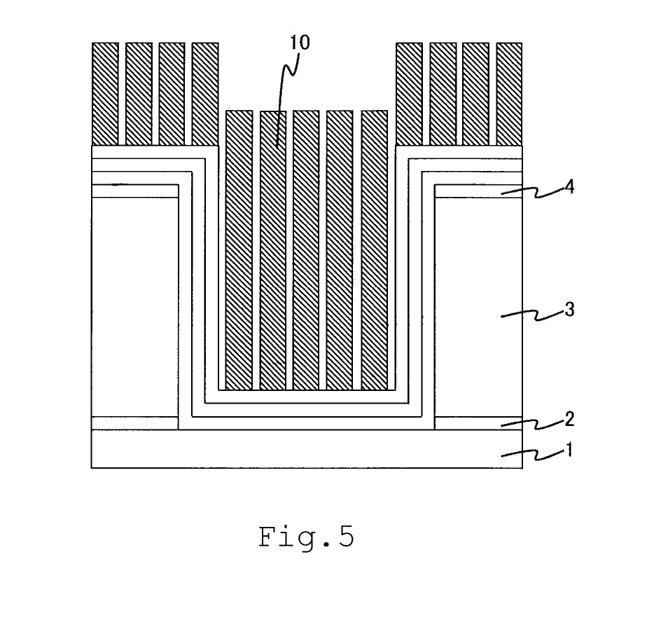

FIG. 5 shows the step of intercalating an atomic or molecular species into the multi-walled carbon nanotubes 9 on the component shown in the schematic view of FIG. 4. The multi-walled carbon nanotubes 9 are intercalated with an atomic or molecular species, so that multi-walled carbon nanotubes 10 having the atomic or molecular species between the walls are formed. For example, the carbon nanotubes are preferably intercalated with at least one atomic or molecular species selected from the group consisting of alkali metals (such as K, Rb, and Li), halogen molecules (such as F₂ and Br₂), and chloride molecules (such as FeCl₃, ZnCl₂, CdCl₂, YCl₃, and AlCl₃). The component shown in the schematic view of FIG. 4 is preferably treated in an atmosphere of a gas of any of these atomic or molecular species. The treatment conditions may be controlled as appropriate depending on the amount of intercalation. For example, the treatment with Br may be performed under the conditions of room temperature, saturated vapor pressure, and 90 minutes. In the treatment, the substrate may be heated, depending on the intercalant species.

The intercalation of the multi-walled carbon nanotubes 9 with an atomic or molecular species increases the diameter of the carbon nanotubes to increase the space occupancy of the carbon nanotubes in the via hole. For example, if the carbon nanotubes have a diameter of 10 nm, the close-packed structure of the carbon nanotubes will have a density of 1.1×10¹² cm⁻². However, if the diameter of the carbon nanotubes is successfully increased to 20 nm by intercalation, a close-packed structure can be obtained even at a carbon nanotube density of 3.0×10¹¹ cm⁻².

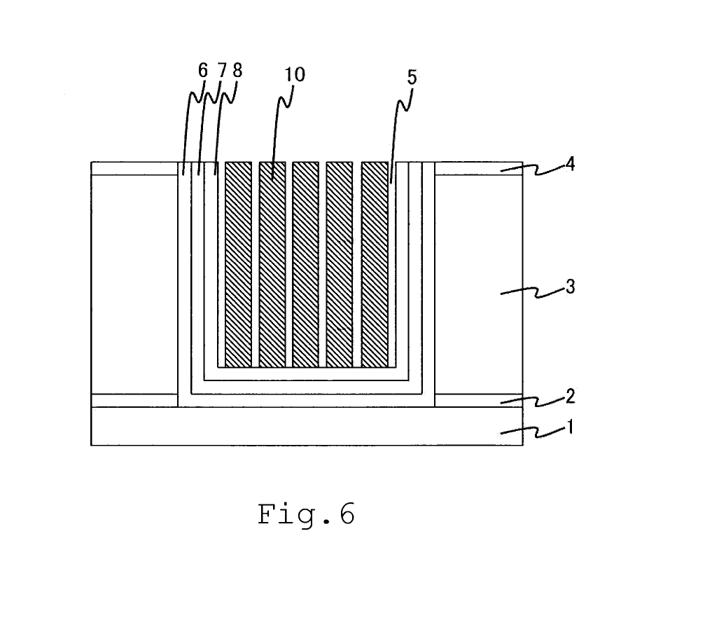

Next, as shown in FIG. 6, planarization is performed using chemical mechanical polishing (CMP), so that a wiring structure is obtained, in which carbon nanotubes 10 intercalated with an atomic or molecular species are formed in the contact hole.

Next, an upper layer wiring 11 is formed on the top of the multi-walled carbon nanotubes 10, so that the semiconductor device shown in FIG. 1 is obtained, which has the wiring structure including the carbon nanotubes.

### Embodiment 2

A semiconductor device having a carbon nanotube wiring according to Embodiment 2 includes a semiconductor integrated circuit having a wiring, an interlayer dielectric formed on the wiring and having a contact hole, a catalyst metal layer formed at the bottom of the contact hole and having catalyst metal particles, multi-walled carbon nanotubes formed on the catalyst metal layer and passing through the contact hole, an upper layer wiring formed on the multi-walled carbon nanotubes, and a first filling film in the contact hole, wherein the carbon nanotube wiring has a gap between the first filling film and the upper layer wiring. Embodiment 2 and other embodiments described below have the common feature that carbon nanotubes 9 and an upper layer wiring 11 form good contact at and near the interface between the carbon nanotubes and the upper wiring.

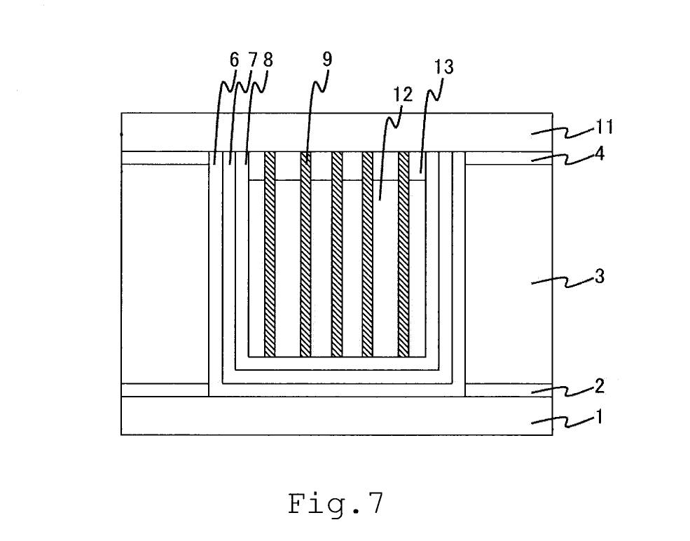

FIG. 7 is a cross-sectional view of an interlayer wiring-containing part of the semiconductor device of the embodiment. FIG. 7 shows a cross-sectional structure of the embodiment, which is a basic feature of the embodiment. An underlying substrate having a semiconductor integrated circuit and other components is omitted from FIG. 7. The semiconductor device of the embodiment includes an underlying substrate having a semiconductor integrated circuit and other components, a lower layer wiring 1 formed on the underlying substrate, an etching stop film 2 on the lower layer wiring 1, an interlayer dielectric 3 on the etching stop film 2, an etching stop film 4 on the interlayer dielectric 3, a contact hole 5 through the etching stop films 2 and 4 and the interlayer dielectric 3, a diffusion preventing film 6 over the bottom and side wall of the contact hole 5, a conductive film 7 on the diffusion preventing film 6, a catalyst metal layer 8 on the conductive film 7, carbon nanotubes 9 grown from a part of the catalyst metal layer 8 at the bottom of the contact hole 5, an upper layer wiring 11 on the carbon nanotubes 9, a first filling film 12 in the contact hole 5, and a gap 13 between the first filling film 12 and the upper layer wiring 11.

The semiconductor device of Embodiment 2 having a carbon nanotube wiring may have the same structure as the semiconductor device of Embodiment 1 having a carbon nanotube wiring, except that the former has the first filling film 12 and the gap 13. Common features will not be described again.

The first filling film 12 is formed to fix the carbon nanotubes 9. The first filling film 12 may be any of an insulating material or a conductive material. The gap 13 is provided between the first filling film 12 and the upper layer wiring 11. The gap 13 is used to isolate the first filling film 12 from the upper layer wiring 11. The depth of the gap 13 is, for example, in a range of 20 nm to 100 nm. If the gap 13 is absent, the upper layer wiring 11 will be in contact with the first filling film 12. If the gap 13 is too shallow, the upper layer wiring 11 can easily come into contact with the first filling film 12, which is not preferred. If the gap 13 is too deep, the materials inside the contact hole 5 may have lower strength, which is also not preferred. If the first filling film 12 is formed using a material reactive with the upper layer wiring 11, the upper layer wiring 11 may be oxidized to increase the resistance of the joint part between the carbon nanotubes 9 and the upper layer wiring 11. In the embodiment, therefore, the gap 13 is provided between the first filling film 12 and the upper layer wiring 11, which is advantageous in that the upper layer wiring 11 is prevented from deteriorating. In the embodiment, therefore, the carbon nanotube wiring can be formed with low contact resistance.

Embodiment 2 does not specifically provide a mode where the carbon nanotubes 9 are intercalated with an atomic or molecular species. In Embodiment 2, however, the carbon nanotubes 9 may also be intercalated with an atomic or molecular species as in Embodiment 1. In Embodiment 2, the first filling film 12 is formed so that the carbon nanotubes 9 are fixed in the part where the first filling film 12 is formed. In such a structure, therefore, the carbon nanotubes 9 are not easily intercalated with an atomic or molecular structure. In Embodiment 2, top end parts of the carbon nanotubes 9, which are regions not surrounded by the first filling film 12, can be intercalated with an atomic or molecular species. In such a case, although the increase in volume is limited, the number of carriers is increased in the atomic or molecular species-intercalated regions of the carbon nanotubes 9, which is advantageous in that low-resistance contact with the upper layer wiring 11 can be formed. It is also advantageous in that as the volume of the carbon nanotubes 9 increases, the contact area between the carbon nanotubes 9 and the upper layer wiring 11 increases.

Next, a method of manufacturing the semiconductor device having the carbon nanotube wiring according to Embodiment 2 will be described. In Embodiment 2, the steps before the formation of the first filling film 12 are the same as those in the manufacturing method of Embodiment 1. Therefore, the step of forming the first filling film 12 and the steps thereafter will be described below.

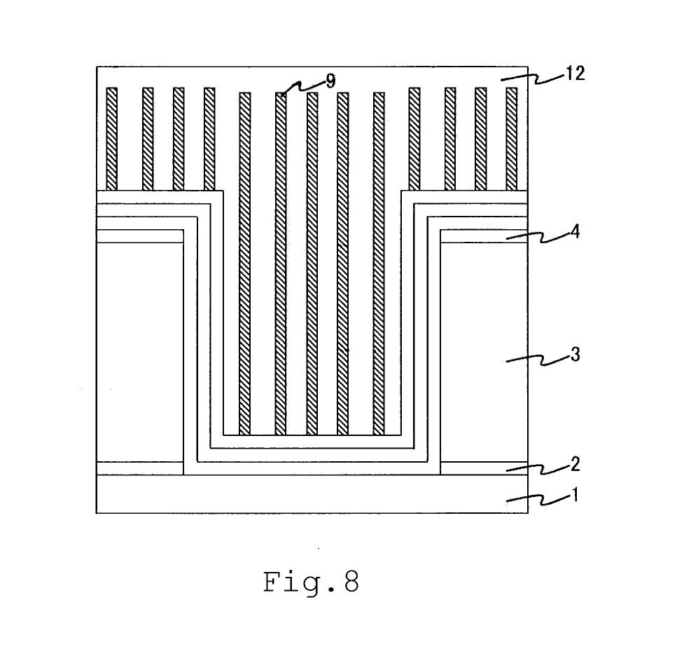

FIG. 8 is a schematic cross-sectional view showing the step of forming the first filling film 12 on the part having the carbon nanotubes 9 grown from the catalyst metal layer 8 as shown in FIG. 4. The first filling film 12 is, for example, an insulating coating formed as a spin on dielectric (SOD) by a spin coating method. After the spin coating, the coating material is cured, for example, by a heat treatment at 400° C.

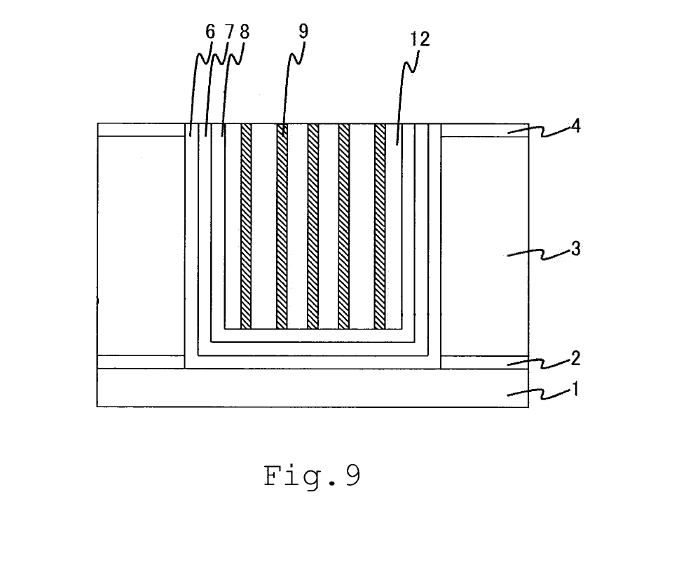

FIG. 9 is a schematic cross-sectional view showing the step of planarizing, by CMP, the part having the first filling film 12 shown in FIG. 8. The planarization removes parts of the carbon nanotubes outside the contact hole and unnecessary part of the first filling film 12.

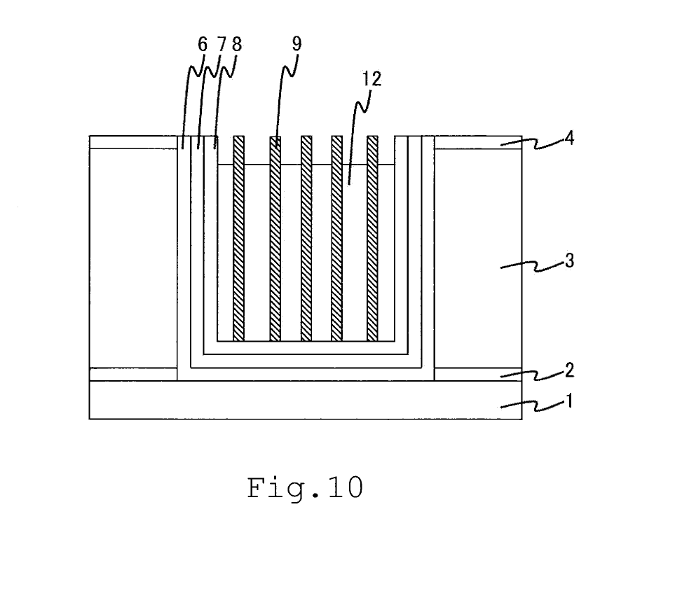

FIG. 10 is a schematic cross-sectional view showing the step of removing part of the first filling film 12 from the planarized part of FIG. 9. Part of the first filling film 12 is removed, which is on the side where the upper layer wiring 11 is to be formed. The region where the first filling film 12 is removed forms the gap 13. When the first filling film 12 is SOD, wet etching is performed, for example, using a solution containing hydrofluoric acid. The wet etching uses a solution capable of partially removing the first filling film 12 while keeping the carbon nanotubes 9 unremoved. The depth of the removed part of the first filling film 12 is, for example, in a range of 20 nm to 100 nm. This step can control the depth of the removed part of the first filling film 12 (the volume of the gap 13 region).

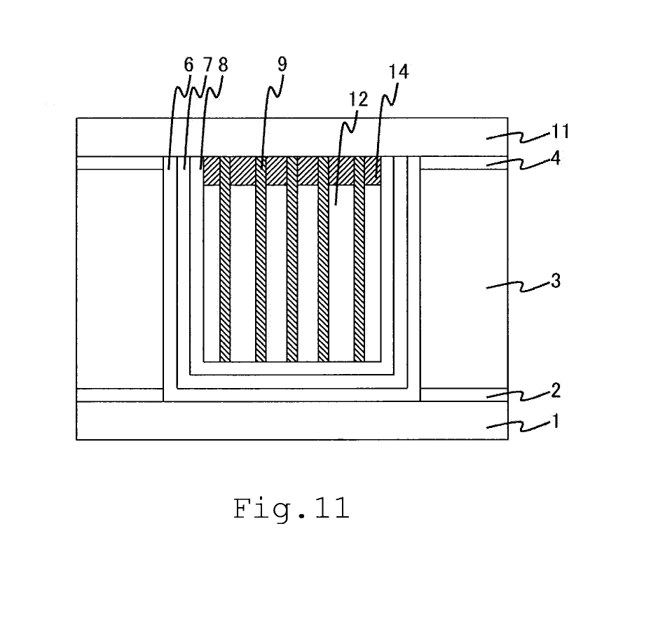

FIG. 11 is a schematic cross-sectional view showing the step of finally forming the upper layer wiring 11 on the part of FIG. 10 where the first tilling film 12 has been partially removed. This step may be the same as the step of forming the upper layer wiring 11 in Embodiment 1. In this step, the method of forming the upper layer wiring 11 is preferably PVD in order to maintain the gap 13.

### Embodiment 3

A semiconductor device having a carbon nanotube wiring according to Embodiment 3 includes a semiconductor integrated circuit having a wiring, an interlayer dielectric formed on the wiring and having a contact hole, a catalyst metal layer formed at the bottom of the contact hole and having catalyst metal particles, multi-walled carbon nanotubes formed on the catalyst metal layer and passing through the contact hole, an upper layer wiring formed on the multi-walled carbon nanotubes, and a first filling film in the contact hole, wherein the carbon nanotube wiring has a second filling film between the first filling film and the upper layer wiring.

FIG. 11 is a cross-sectional view of an interlayer wiring-containing part of the semiconductor device of the embodiment. FIG. 11 shows a cross-sectional structure of the embodiment, which is a basic feature of the embodiment. An underlying substrate having a semiconductor integrated circuit and other components is omitted from FIG. 11. The semiconductor device of the embodiment includes an underlying substrate having a semiconductor integrated circuit and other components, a lower layer wiring 1 formed on the underlying substrate, an etching stop film 2 on the lower layer wiring 1, an interlayer dielectric 3 on the etching stop film 2, an etching stop film 4 on the interlayer dielectric 3, a contact hole 5 through the etching stop films 2 and 4 and the interlayer dielectric 3, a diffusion preventing film 6 over the bottom and side wall of the contact hole 5, a conductive film 7 on the diffusion preventing film 6, a catalyst metal layer 8 on the conductive film 7, carbon nanotubes 9 grown from a part of the catalyst metal layer 8 at the bottom of the contact hole 5, an upper layer wiring 11 on the carbon nanotubes 9, a first filling film 12 in the contact hole 5, and a second filling film 14 between the first filling film 12 and the upper layer wiring 11.

The semiconductor device of Embodiment 3 having a carbon nanotube wiring may have the same structure as the semiconductor device of Embodiment 2 having a carbon nanotube wiring, except that the former has the second filling film 14. Common features will not be described again. Top end parts of the carbon nanotubes 9 may be intercalated with the atomic or molecular species.

Like the gap 13 in Embodiment 2, the second filling film 14 is also a component for isolating the first filling film 12 from the upper layer wiring 11. A conductor or an insulator may be used to form the second filling film 14. Materials other than oxides are preferably used in order to prevent oxidation of the upper layer wiring 11. Specifically, for example, Ti may be used as a material to form the second filling film 14. The depth of the conductor or the insulator 14 is preferably, for example, in a range of 10 nm to 100 nm. In the embodiment, the upper layer wiring 11 and the first filling film 12 are in contact with the conductor or insulator 14. When a material capable of preventing deterioration of the upper layer wiring 11 is used to form the second filling film 14, good contact can be obtained between the carbon nanotubes 9 and the upper layer wiring 11, which is advantageous.

Next, a method of manufacturing the semiconductor device having the second filling film 14 will be described. The steps until part of the first filling film 12 is removed are the same as those in the manufacturing method of Embodiment 2. Therefore, the step of forming the second filling film 14 and the steps thereafter will be described.

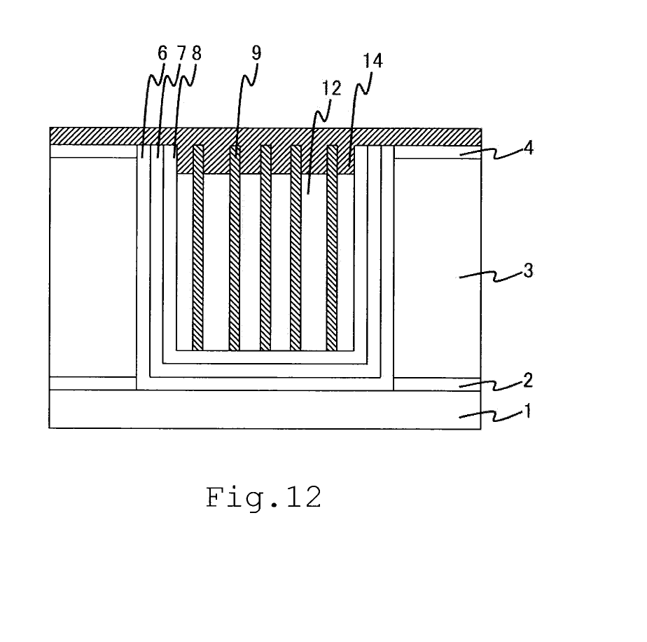

FIG. 12 is a schematic cross-sectional view showing the step of depositing a material for the second filling film 14 on the part of FIG. 10 where the first filling film 12 has been partially removed. The deposition method may be PVD or CVD.

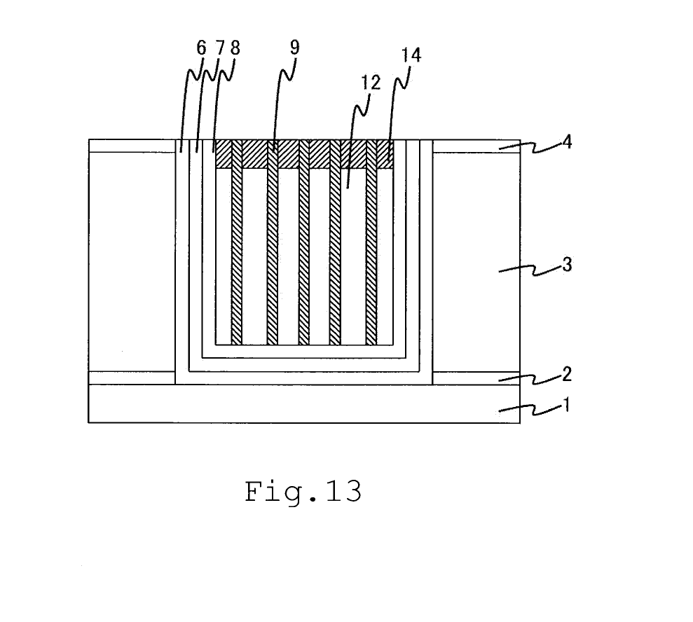

FIG. 13 is a schematic cross-sectional view showing the step of performing a planarization treatment on the part of FIG. 12 where the material for the second filling film 14 is deposited. The planarization treatment is performed in such a way that the surfaces of the carbon nanotubes 9 are exposed. CMP, reactive ion etching (RIE), or the like may be used in the planarization. The upper layer wiring 11 is then formed as in Embodiment 1, so that the semiconductor device of Embodiment 3 having the carbon nanotube wiring as shown in the schematic view of FIG. 11 is obtained.

### Embodiment 4

A semiconductor device having a carbon nanotube wiring according to Embodiment 4 includes a semiconductor integrated circuit having a wiring, an interlayer dielectric formed on the wiring and having a contact hole, a catalyst metal layer formed at the bottom of the contact hole and having catalyst metal particles, multi-walled carbon nanotubes formed on the catalyst metal layer and passing through the contact hole, an upper layer wiring formed on the multi-walled carbon nanotubes, and a first filling film in the contact hole, wherein top end parts of the carbon nanotubes are inserted in the first filling film.

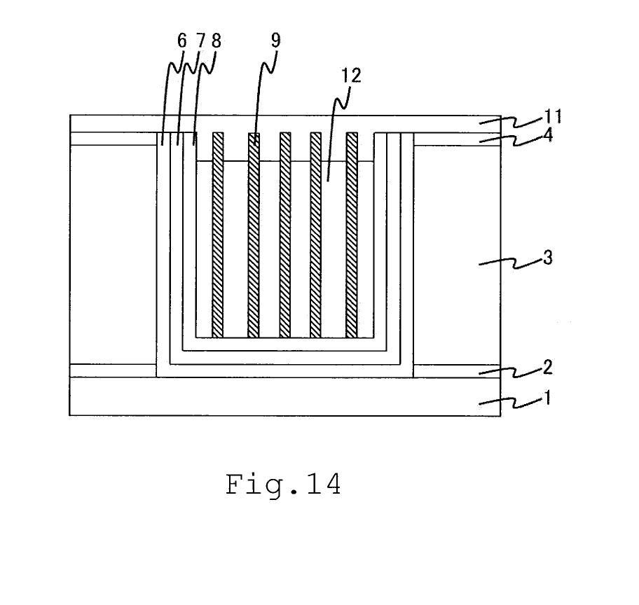

FIG. 14 is a cross-sectional view of an interlayer wiring-containing part of the semiconductor device of the embodiment. FIG. 14 shows a cross-sectional structure of the embodiment, which is a basic feature of the embodiment. An underlying substrate having a semiconductor integrated circuit and other components is omitted from FIG. 14. The semiconductor device of the embodiment includes an underlying substrate having a semiconductor integrated circuit and other components, a lower layer wiring 1 formed on the underlying substrate, an etching stop film 2 on the lower layer wiring 1, an interlayer dielectric 3 on the etching stop film 2, an etching stop film 4 on the interlayer dielectric 3, a contact hole 5 through the etching stop films 2 and 4 and the interlayer dielectric 3, a diffusion preventing film 6 over the bottom and side wall of the contact hole 5, a conductive film 7 on the diffusion preventing film 6, a catalyst metal layer 8 on the conductive film 7, carbon nanotubes 9 grown from a part of the catalyst metal layer 8 at the bottom of the contact hole 5, an upper layer wiring 11 in which top end parts of the carbon nanotubes 9 are inserted, and a first filling film 12 in the contact hole 5.

The semiconductor device of Embodiment 4 having a carbon nanotube wiring may have the same structure as the semiconductor device of Embodiment 2 having a carbon nanotube wiring, except that the former does not have the gap 13 and that in the former, top end parts of the carbon nanotubes 9 are inserted in the upper layer wiring 11. Common features will not be described again. Top end parts of the carbon nanotubes 9 may be intercalated with the atomic or molecular species.

The embodiment has the feature that top end parts of the carbon nanotubes 9 are inserted in the upper layer wiring 11. Thus, even if the upper layer wiring 11 deteriorates at the interface between the upper layer wiring 11 and the first filling film 12, the upper layer wiring 11 can form good contact with the carbon nanotubes 9 because the tops of the carbon nanotubes 9 are apart from the interface. The depth of the insertion of the carbon nanotubes 9 in the upper layer wiring 11 is preferably in a range of 10 nm to 100 nm. If the depth of the insertion is too shallow, the interface between the first filling film 12 and the upper layer wiring 11 can be too close to the tops of the carbon nanotubes 9, which is not preferred. If the depth of the insertion is too deep, the materials inside the contact hole 5 may have lower strength, which is also not preferred.

Next, a method of manufacturing the semiconductor device in which top end parts of the carbon nanotubes 9 are inserted in the upper layer wiring 11 will be described. The steps until part of the first filling film 12 is removed are the same as those in the manufacturing method of Embodiment 2. Therefore, the step of forming the upper layer wiring and the steps thereafter will be described.

The material for the upper layer wiring is deposited on the part of FIG. 10 where the first filling film 12 has been partially removed, so that the upper layer wiring 11 according to Embodiment 4 is formed. The deposition method may be PVD or CVD. After the deposition, a carbon nanotube wiring composed of the carbon nanotubes 9 whose top end parts are embedded in the upper layer wiring 11 is obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
a lower layer wiring on the substrate;
an interlayer dielectric on the lower layer wiring having a contact hole;
a catalyst metal layer at the bottom of the contact hole having catalyst metal particles;
multi-walled carbon nanotubes on the catalyst metal layer passing through the contact hole; and
an upper layer wiring on the multi-walled carbon nanotubes, wherein
the multi-walled carbon nanotubes are intercalated with an atomic or molecular species.

2. The device according to claim 1, wherein the atomic or molecular species is at least one selected from K, Rb, Li, F₂, Br₂, FeCl₃, ZnCl₂, CdCl₂, YCl₃, and AlCl₃.

3. The device according to claim 1, wherein the multi-walled carbon nanotubes have a concentric cylindrical structure or a scroll shape.

4. The device according to claim 1, further comprising:
a first filling film in the contact hole; and
a gap or a second filling film between the upper layer wiring and the first filling film in the contact hole.

5. The device according to claim 1, further comprising a first filling film in the contact hole, wherein
top end parts of the multi-walled carbon nanotubes are inserted in the upper layer wiring.

6. A method of manufacturing a semiconductor device, comprising:
forming an interlayer dielectric on a substrate;
forming a contact hole through the interlayer dielectric;
forming a catalyst metal layer at the contact hole;
growing multi-walled carbon nanotubes from the catalyst metal layer; and
intercalating the multi-walled carbon nanotubes with an atomic or molecular species.

7. The method according to claim 6, wherein the atomic or molecular species is at least one selected from K, Rb, Li, F₂, Br₂, FeCl₃, ZnCl₂, CdCl₂, YCl₃, and AlCl₃.

8. A semiconductor device, comprising:
a substrate;
a lower layer wiring on the substrate;
an interlayer dielectric on the lower layer wiring having a contact hole;
a catalyst metal layer at the bottom of the contact hole having catalyst metal particles;
multi-walled carbon nanotubes on the catalyst metal layer passing through the contact hole;
an upper layer wiring on the multi-walled carbon nanotubes, and
a first filling film in the contact hole, wherein
a gap is provided between the first filling film and the upper layer wiring,
a second filling film is provided between the first filling film and the upper layer wiring, or
top end parts of the multi-walled carbon nanotubes are embedded in the upper layer wiring.

9. The device according to claim 8, wherein a gap depth is in a range of 10 nm to 100 nm.

10. The device according to claim 8, wherein a second filling film depth is in a range of 10 nm to 100 nm.

11. The device according to claim 8, wherein a top end parts depth is in a range of 10 nm to 100 nm.

12. The device according to claim 8, wherein the second filling film is a conductor or an insulator.
